(19) United States
(12) Patent Application Publication
(10) Pub. No.: US 2021/0328078 A1
(43) Pub. Date: Oct. 21, 2021

(54) Merged PiN Schottky (MPS) Diode With Plasma Spreading Layer And Manufacturing Method Thereof

(71) Applicants: Xiaotian Yu, Los Angeles, CA (US); Zheng Zuo, Los Angeles, CA (US); Ruigang Li, Los Angeles, CA (US)

(72) Inventors: Xiaotian Yu, Los Angeles, CA (US); Zheng Zuo, Los Angeles, CA (US); Ruigang Li, Los Angeles, CA (US)

(73) Assignee: AZ Power, Inc, Culver City, CA (US)

(21) Appl. No.: 17/235,894

(22) Filed: Apr. 20, 2021

Related U.S. Application Data
(60) Provisional application No. 63/012,894, filed on Apr. 20, 2020.

(51) Int. Cl. H01L 29/872; H01L 29/16; H01L 29/06; H01L 29/45; H01L 29/47; H01L 21/04; H01L 29/66

(52) U.S. Cl. CPC H01L 29/872; H01L 29/1608; H01L 29/0692; H01L 29/45; H01L 29/6606; H01L 21/0465; H01L 21/0485; H01L 21/0495; H01L 29/47

(57) ABSTRACT

A method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; forming a plasma spreading layer; depositing and patterning a first Ohmic contact metal on the regions with the second conductivity type; depositing a Schottky contact metal on top of the entire epitaxial layer; and forming a second Ohmic contact metal on a backside of the substrate. In another embodiment, the step of forming a plurality of regions with a second conductivity type may include steps of depositing and patterning a mask layer on the epitaxial layer, implanting P-type dopant into the epitaxial layer, and removing the mask layer.

### CROSS-REFERENCE TO RELATED APPLICATIONS

This application claims priority under 35 U.S.C. § 119 (e) to U.S. Provisional Patent Application Ser. No. 63/012,894, filed on Apr. 20, 2020, the entire contents of which are hereby incorporated by reference.

### FIELD OF THE INVENTION

The present invention relates to a power diode structure, and more particularly to a merged PiN junction Schottky (MPS) diode with enhanced reliability under a surge current.

### BACKGROUND OF THE INVENTION

Power devices include power diodes and power switching transistors. Power diodes have two modes of operation in circuit applications, which are conduction mode and blocking mode. For the conduction mode, in addition to nominal current conditions, there is an occasional surge current condition. Under the abnormal conditions with surge current, the diode may have instant energy overshoot and chip temperature rise, resulting in device failure.

Power devices are expected to endure high current stresses under surges caused by circuit failure or lightening. Usually a great amount of energy, caused by high current multiplied by high voltage drop, flows into the device in quite a short time, leading to rapidly raised temperature and possibly a device failure. Surge capability is a key performance index which describes the robustness of power devices under extreme operating conditions. Devices with preeminent surge capability can dissipate such energy efficiently without a failure, thus offering a higher safety margin to the power system.

Silicon carbide semiconductor has two times larger bandgap compared with Silicon semiconductor. With a higher critical electric field, higher thermal conductivity, lower intrinsic carrier concentration, and higher saturation drift velocity, silicon carbide semiconductor has become an ideal candidate for high voltage, high temperature and high-power devices.

There are two technical routes for commercial devices based on silicon carbide power diodes, namely junction barrier Schottky (JBS) diode structure and merged PiN Schottky (MPS) diode structure.

For silicon carbide (SiC) materials, the Junction Barrier Schottky (JBS) diode is widely used. Armed with excellent characteristics of SiC material and characterized by alternatively arranged small P+ regions in N− drift layer, it has received large attention for its low forward voltage drop and low reverse leakage current. Merged PiN Schottky (MPS) diode was proposed based on the JBS diode structure, with merged large P+ regions into the active region. PN junctions formed by these large P+ regions will turn on under high current flows. Large amount of minority carriers will be injected into the drift layer, providing a lower resistivity and a higher current conduction capability. Thus, it offers higher surge capability compared to traditional JBS diode, as well as preserving a low forward voltage drop and reverse leakage current at the same time.

### SUMMARY OF THE INVENTION

In one aspect, a merged PiN Schottky (MPS) diode may include a silicon carbide substrate having a first conductivity type, an epitaxial layer with the first conductivity type formed on the substrate, In one embodiment, the doping concentration in the epitaxial layer is lower than that in the substrate. The merged PiN Schottky (MPS) diode may further include a plurality of regions having a second conductivity type different from the first conductivity type, and formed under a top surface of the epitaxial layer.

A first Ohmic contact metal is formed on top of each of the regions of the second conductivity type, and a Schottky contact metal is placed on top of the entire epitaxial layer to form a Schottky junction. A second Ohmic contact is formed by a cathode electrode on the back side of the substrate.

In one embodiment, the first conductivity is N type, and the second conductivity type is P type. It is noted that in the merged PiN Schottky (MPS) diode structure, a PN junction can be formed by a P+ region, and a N-type drift region can be turned on under surge current condition, forming a parallel operation mode between the PN junction and the Schottky junction, providing device with better surge current capability.

In a merged PiN Schottky (MPS) diode structure, the PN junction formed by the P+ region and the N-type drift region can be turned on under surge current condition, forming a parallel operation mode between the PN junction and the Schottky junction, providing device with better surge current capability. The shape, size and arrangement of the P+ region largely affect the electrical characteristics of the merged PiN Schottky (MPS) diode in the event of a high current surge.

In one embodiment, the merged PiN Schottky (MPS) diode may have two hexagonal cells, the central hexagonal P+ island and the hexagonal P+ outer ring isolated from each other. Under surge current condition, the PN junctions formed between the P+ regions and the N-type drift region will be turned on. Due to the bipolar effect, minority carriers are injected on both sides of the PN junction to form electron-hole plasmas. These plasmas are first generated under the PN junction. At the moment of the surge current occurs, it is difficult for these plasmas to rapidly spread to other part of the devices, same for the surge current and the heat generated inside the device. As a result, a localized heating phenomenon that causes the device to fail prematurely is inevitable.

Based on the problem described above, this patent proceeds from the structural design of the device, connecting the P+ regions through the structure of the plasma spreading layer. Once the surge current occurs, the plasma spreading layer can help rapidly diffusing the plasma to other drift regions, resulting in the surge current and the heat generated inside the device evenly dispersed over the device to avoid localized heating.

In another aspect, a method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; forming a plasma spreading layer in each region; depositing and patterning an Ohmic contact metal on the regions with the second conductivity type; depositing a Schottky contact metal on top of the entire epitaxial layer; and forming an Ohmic contact metal on a backside of the substrate.

In one embodiment, the epitaxial layer is made of N-type silicon carbide. In another embodiment, the step of forming a plurality of regions with a second conductivity type under a top surface of the epitaxial layer may include steps of depositing and patterning a mask layer on the epitaxial layer, implanting P-type dopant into the epitaxial layer, and removing the mask layer. It is noted that the dopant can be aluminum or boron.

In a further embodiment, the step of depositing and patterning an Ohmic contact metal on the regions may include a step of annealing the Ohmic metal to enable the metal to be in direct contact with the epitaxial layer. In still a further embodiment, the step of depositing a Schottky contact metal on top of the entire epitaxial layer may include a step of conducting a low temperature annealing of the Schottky contact metal.

### BRIEF DESCRIPTION OF THE DRAWINGS

FIG. 1 is a cross-section view of the merged PiN Schottky (MPS) diode in the present invention.

FIG. 2 is a schematic view of a layout design of a merged PiN Schottky (MPS) diode with two types of hexagonal cells.

FIG. 3 is a schematic view of a merged PiN Schottky (MPS) diode with a first type of plasma spreading layer.

FIG. 4 is a schematic view of the merged PiN Schottky (MPS) diode in FIG. 3 with one layer of hexagonal cells between the adjacent plasma spreading layer.

FIG. 5 is a schematic view of the merged PiN Schottky (MPS) diode in FIG. 3 with two layers of hexagonal cells between the adjacent plasma spreading layer.

FIG. 6 is a schematic view of a merged PiN Schottky (MPS) diode with a second type of plasma spreading layer.

FIG. 7 is a schematic view of the merged PiN Schottky (MPS) diode in FIG. 6 with one layer of hexagonal cells between the adjacent plasma spreading layer.

FIG. 8 is a schematic view of the merged PiN Schottky (MPS) diode in FIG. 6 with two layers of hexagonal cells between the adjacent plasma spreading layer.

FIG. 9 is a schematic view of a merged PiN Schottky (MPS) diode with a third type of plasma spreading layer.

FIG. 10 is a schematic view of the merged PiN Schottky (MPS) diode in FIG. 9 with one layer of hexagonal cells between the adjacent plasma spreading layer.

FIG. 11 is a schematic view of the merged PiN Schottky (MPS) diode in FIG. 9 with two layers of hexagonal cells between the adjacent plasma spreading layer.

FIG. 12 is a schematic view of a merged PiN Schottky (MPS) diode with a fourth type of plasma spreading layer.

FIG. 13 is a schematic view of the merged PiN Schottky (MPS) diode in FIG. 12 with one layer of hexagonal cells between the adjacent plasma spreading layer.

FIG. 14 is a schematic view of the merged PiN Schottky (MPS) diode in FIG. 12 with two layers of hexagonal cells between the adjacent plasma spreading layer.

FIG. 15 is a schematic view of a merged PiN Schottky (MPS) diode with a cross-networking plasma spreading layer after symmetric transformation of plasma spreading layer shown in FIG. 6.

FIG. 16 is a schematic view of a merged PiN Schottky (MPS) diode with a cross-networking plasma spreading layer after symmetric transformation of plasma spreading layer shown in FIG. 7.

FIG. 17 is a schematic view of a merged PiN Schottky (MPS) diode with a cross-networking plasma spreading layer after symmetric transformation of plasma spreading layer shown in FIG. 8.

FIG. 18 is a schematic view of a merged PiN Schottky (MPS) diode with a cross-networking plasma spreading layer after symmetric transformation of plasma spreading layer shown in FIG. 12.

FIG. 19 is a schematic view of a merged PiN Schottky (MPS) diode with a cross-networking plasma spreading layer after symmetric transformation of plasma spreading layer shown in FIG. 13.

FIG. 20 is a schematic view of a merged PiN Schottky (MPS) diode with a cross-networking plasma spreading layer after symmetric transformation of plasma spreading layer shown in FIG. 14.

FIG. 21 is a schematic view of a merged PiN Schottky (MPS) diode with a cross-networking plasma spreading layer with the combination of the plasma spreading layers shown in FIGS. 3 and 15.

FIG. 22 is a schematic view of a merged PiN Schottky (MPS) diode with a cross-networking plasma spreading layer with the combination of the plasma spreading layers shown in FIGS. 4 and 16.

FIG. 23 is a schematic view of a merged PiN Schottky (MPS) diode with a cross-networking plasma spreading layer with the combination of the plasma spreading layers shown in FIGS. 5 and 17.

FIG. 24 is a schematic view of a merged PiN Schottky (MPS) diode with a cross-networking plasma spreading layer with the combination of the plasma spreading layers shown in FIGS. 9 and 18.

FIG. 25 is a schematic view of a merged PiN Schottky (MPS) diode with an alternative cross-networking plasma spreading layer.

FIG. 26 is a schematic view of a merged PiN Schottky (MPS) diode with another cross-networking plasma spreading layer.

FIGS. 27A to 27G illustrate flow diagrams of the method for manufacturing a merged PiN Schottky (MPS) diode in the present invention.

FIG. 28 is a block diagram illustrating the method for manufacturing a merged PiN Schottky (MPS) diode in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

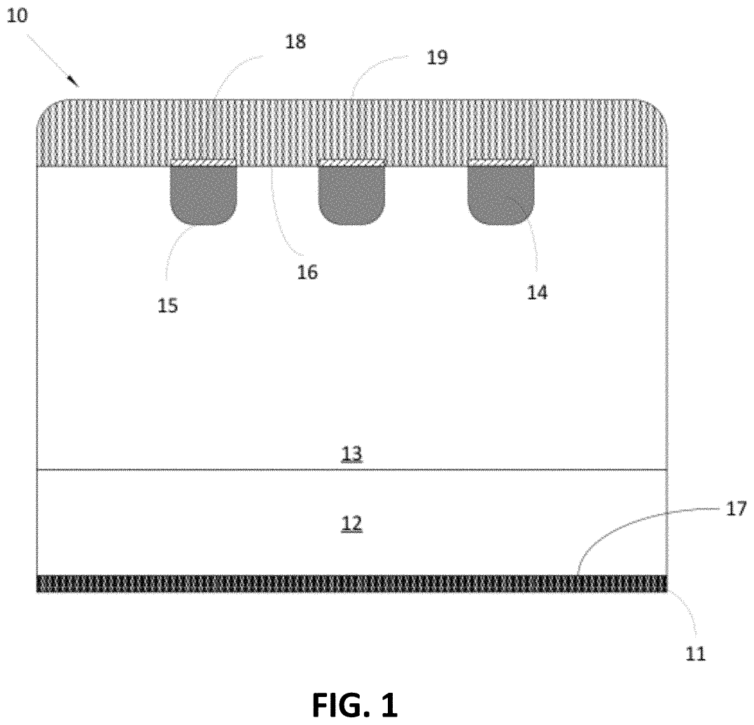

In one aspect as shown in FIG. 1, a merged PiN Schottky (MPS) diode 10 may include a silicon carbide substrate 12 having a first conductivity type, an epitaxial layer 13 with the first conductivity type formed on the substrate 12. In one embodiment, the doping concentration in the epitaxial layer 13 is lower than that in the substrate 12. The merged PiN Schottky (MPS) diode 10 may further include a plurality of regions 14 having a second conductivity type different from the first conductivity type, and formed on the surface of the epitaxial layer 13.

A first Ohmic contact metal 18 is formed on top of each of the regions of the second conductivity type, and a Schottky contact metal 19 is placed on top of the entire epitaxial layer 13 to form a Schottky junction 16. A second Ohmic contact 17 is formed by a cathode electrode 11 on the back side of the substrate 12.

In one embodiment, the first conductivity is N type, and the second conductivity type is P type. It is noted that in the merged PiN Schottky (MPS) diode structure, a PN junction can be formed by a P+ region 14, and a N-type drift region 15 can be turned on under surge current condition, forming a parallel operation mode between the PN junction and the Schottky junction 16, providing device with better surge current capability.

It is noted that the layout design of the merged PiN Schottky (MPS) diode 10 can be strip cell structure, circle cell structure or polygon cell structure. The one-dimensional strip structure has the drawback that the P+ region occupies too much active area, resulting in insufficient Schottky area for normal current operation, leading to a large forward voltage drop of the device. However, two-dimensional circles will also leads to a large P+ percentage because circular cells cannot form a close-packed layout. Therefore, compared with regular polygon cell structure, the device will also have larger forward voltage drop due to inadequate Schottky area under normal current operation.

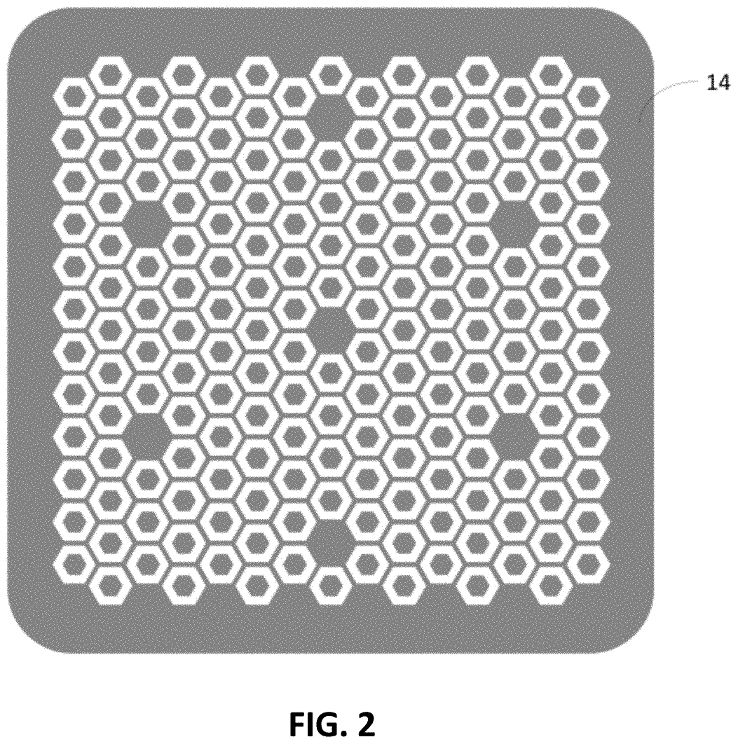

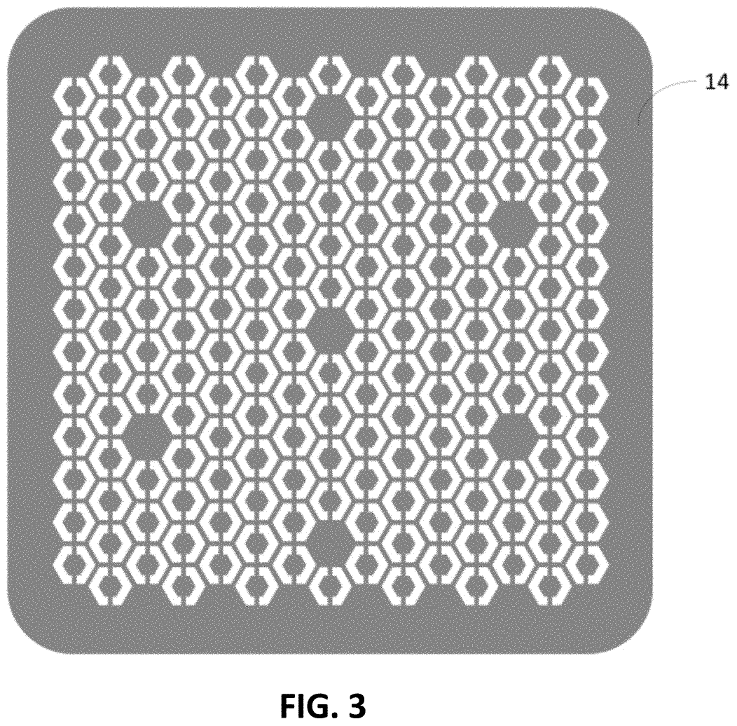

In one embodiment, FIG. 2 illustrates a merged PiN Schottky (MPS) diode structure, and as shown in FIG. 3, a plasma spreading layer is being introduced on the MPS diode in FIG. 2. The plasma spreading layer design can connect the P+ hexagonal islands and the outer P+ rings. During surge current shock, the PN junction formed by the large P+ hexagon region 14 and N-type drift layer 15 is first turned on, then the bipolar effect takes place and the electron-holes are created. With the plasma spreading layer, the electron-hole plasma can be dispersed to the whole area of the device, so the high surge current and dissipated energy can be evenly distributed within the device to effectively prevent the device from being damaged caused by localized heating, and to improve the surge current capability of the device.

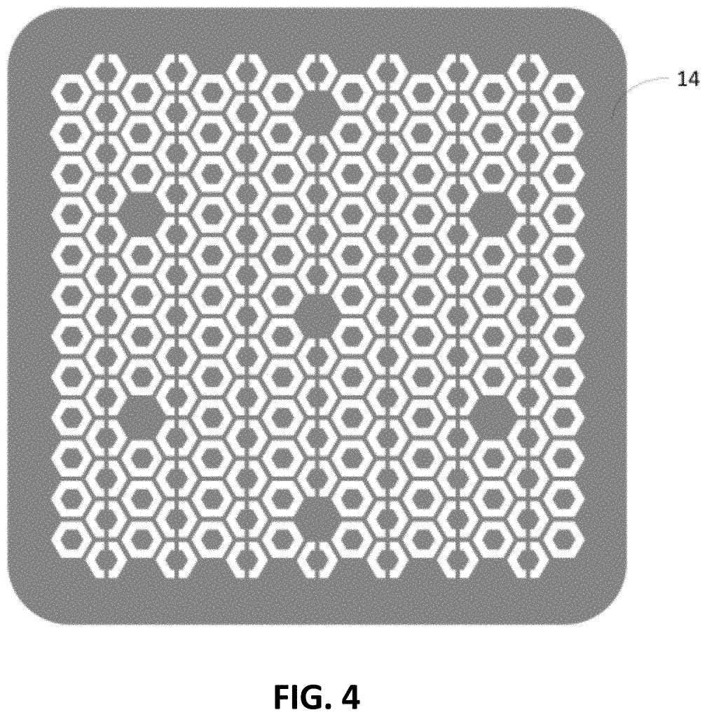

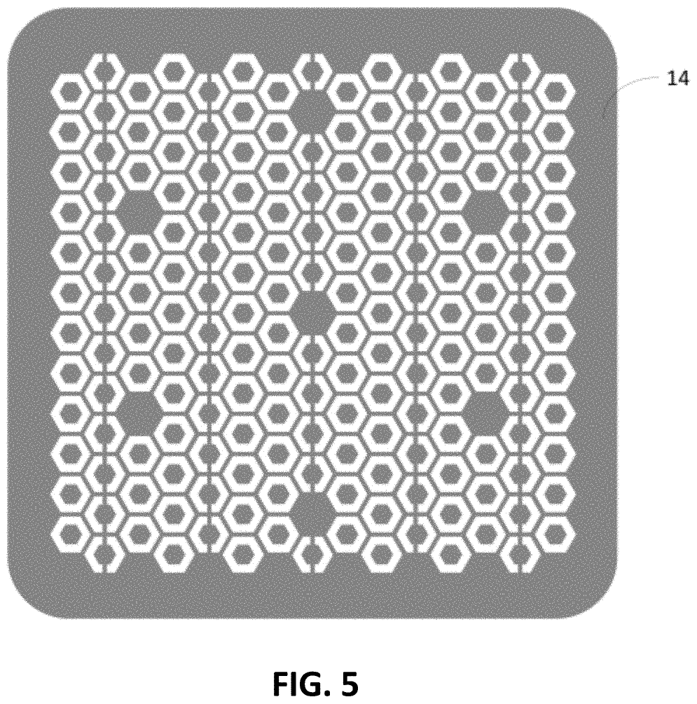

According to FIG. 3, the merged PiN Schottky (MPS) diode with different arrangements of the plasma spreading layer can be obtained, as shown in FIGS. 4 and 5. Furthermore, there can be n layers of hexagonal cells between the adjacent the plasma spreading layers, where n can be 0 to 200.

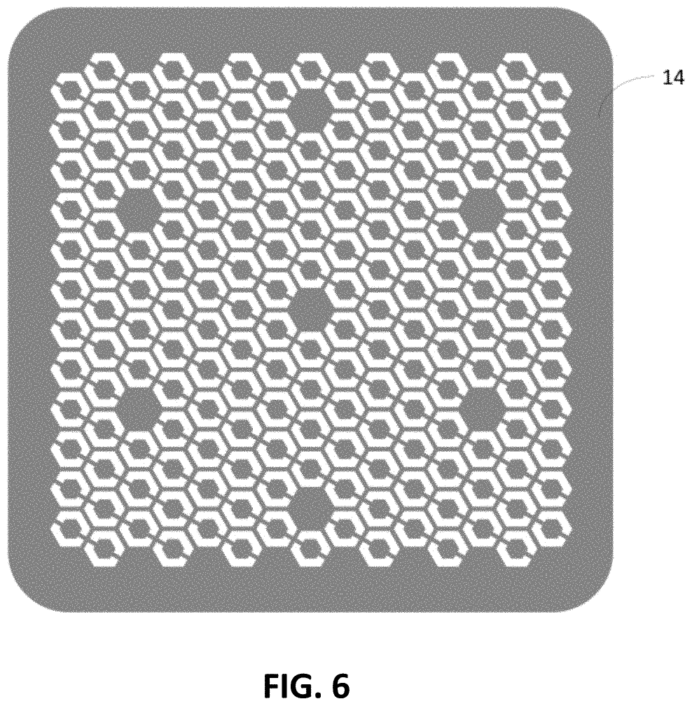

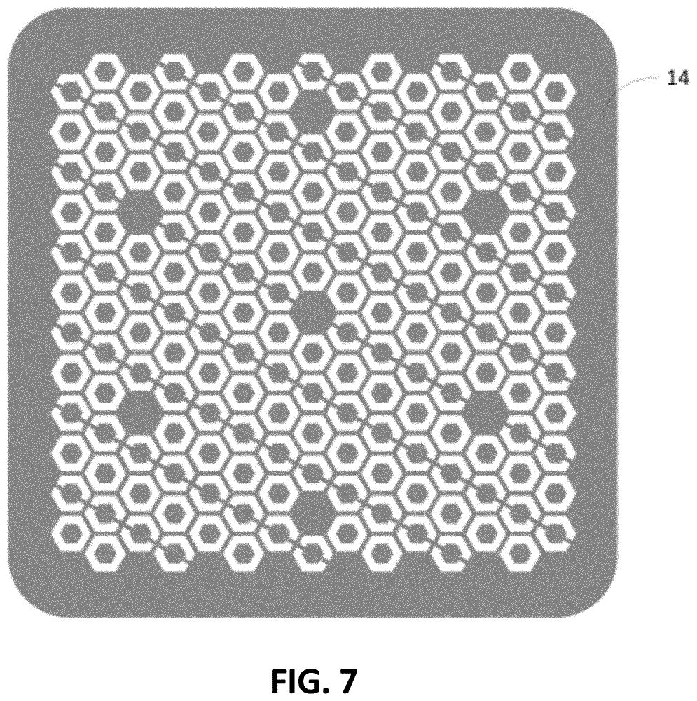

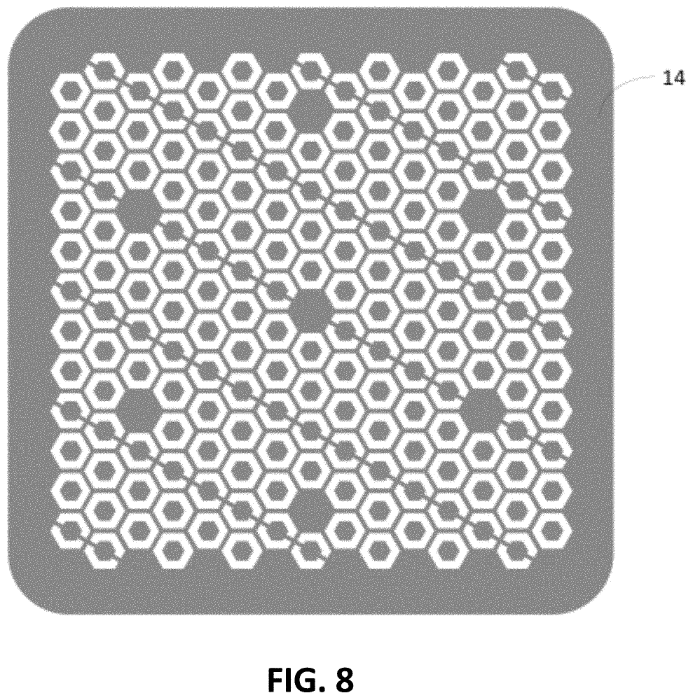

As shown in FIG. 6 for a second embodiment, a plasma spreading layer can be rotated by 60 degrees from that in FIG. 3. According to FIG. 6, the merged PiN Schottky (MPS) diode with different arrangements of the plasma spreading layer can be obtained, as shown in FIGS. 7 and 8. Furthermore, there can be n layers of hexagonal cells between the adjacent plasma spreading layer, where n can be 0 to 200.

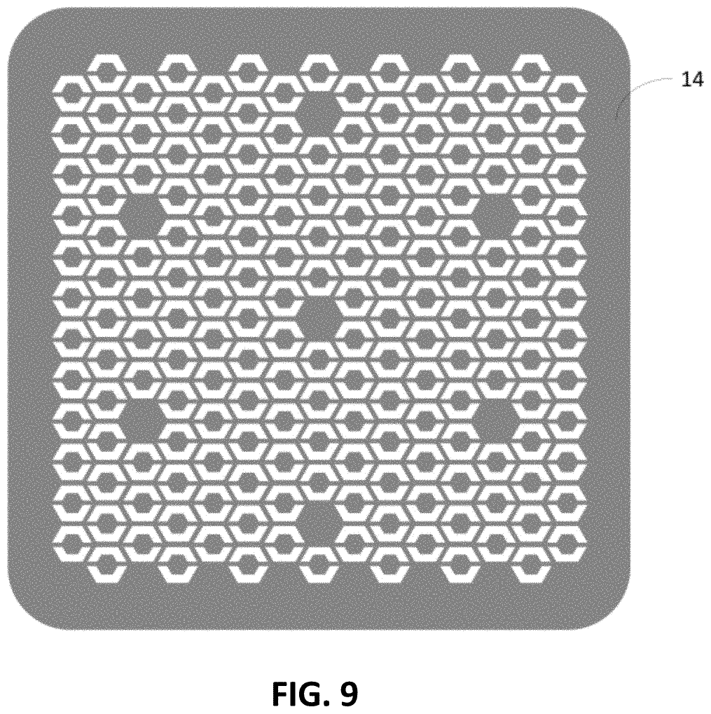

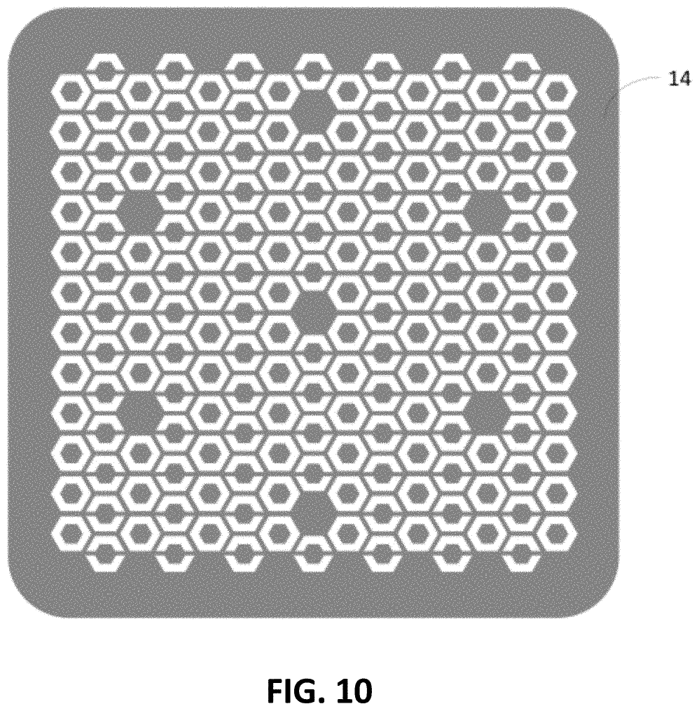

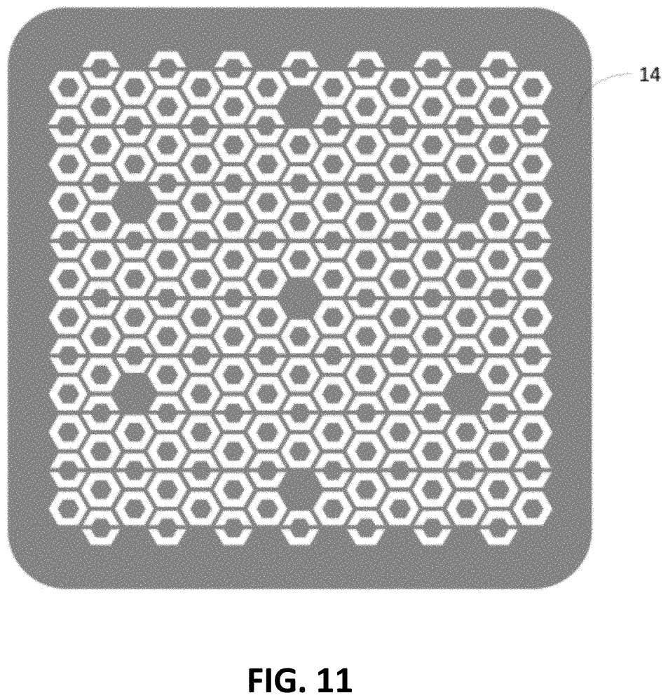

FIG. 9 shows a third embodiment of a plasma spreading layer in the present invention. Similarly, the merged PiN Schottky (MPS) diode with different arrangements of the plasma spreading layer can be obtained, as shown in FIGS. 10 and 11. Furthermore, there can be n layers of hexagonal cells between the adjacent plasma spreading layer, where n can be 0 to 200.

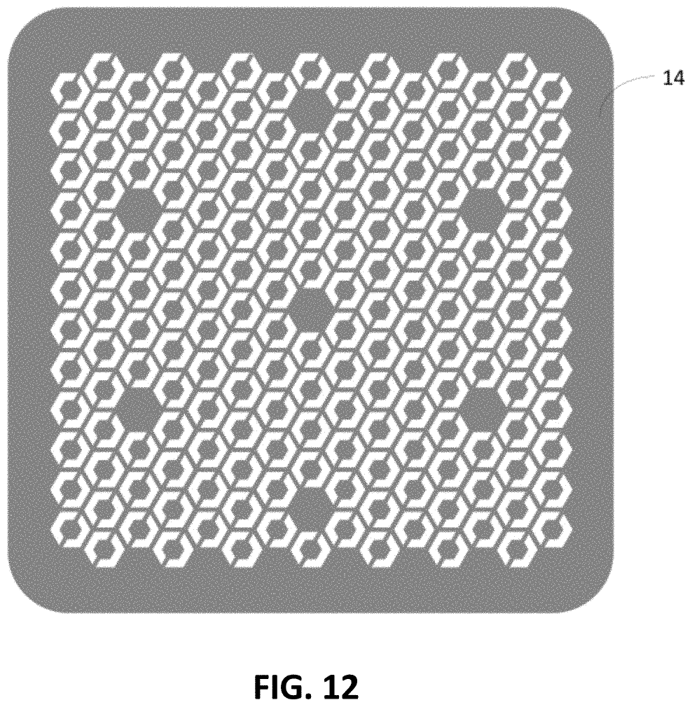

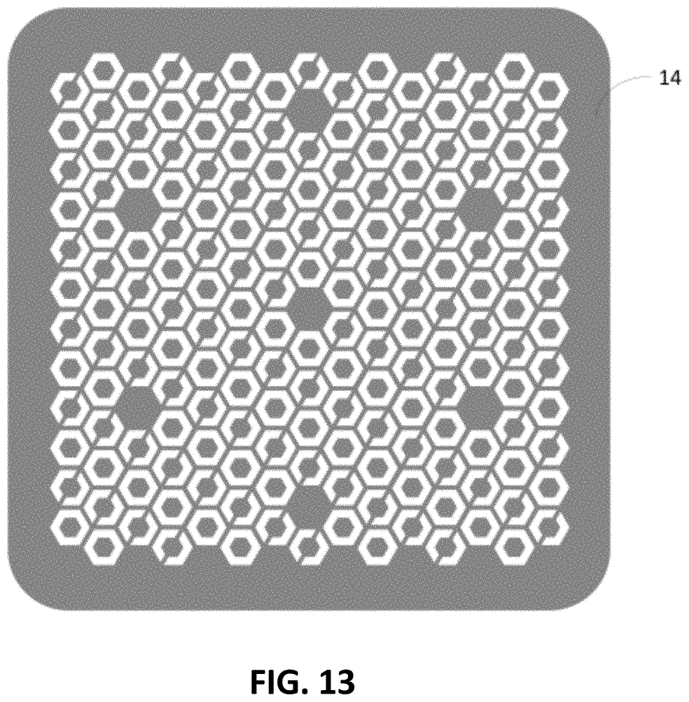

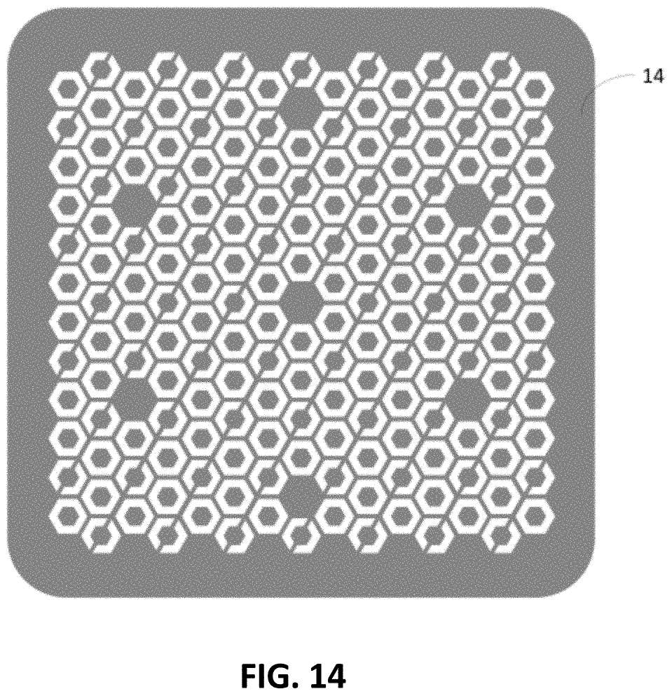

As shown in FIG. 12 for a fourth embodiment, a plasma spreading layer can be rotated by 60 degrees from that in FIG. 9. According to FIG. 12, the merged PiN Schottky (MPS) diode with different arrangements of the plasma spreading layer can be obtained, as shown in FIGS. 13 and 14. Furthermore, there can be n layers of hexagonal cells between the adjacent plasma spreading layer, where n can be 0 to 200.

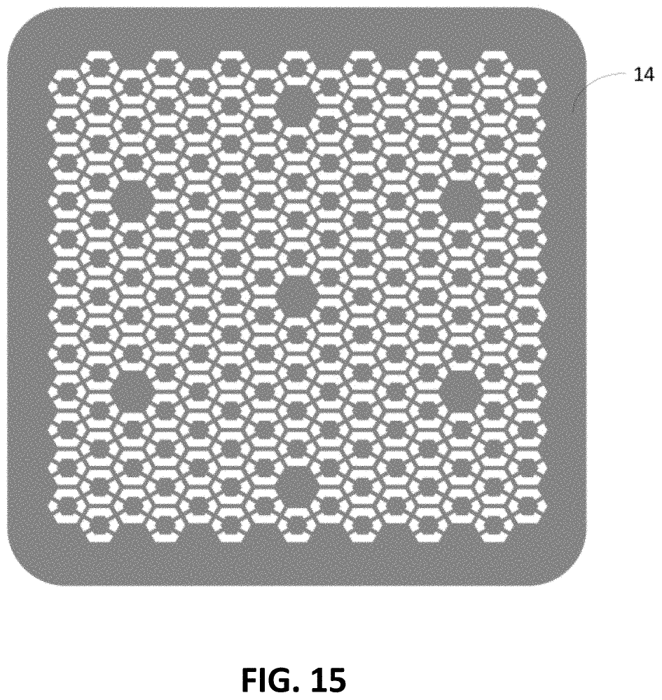

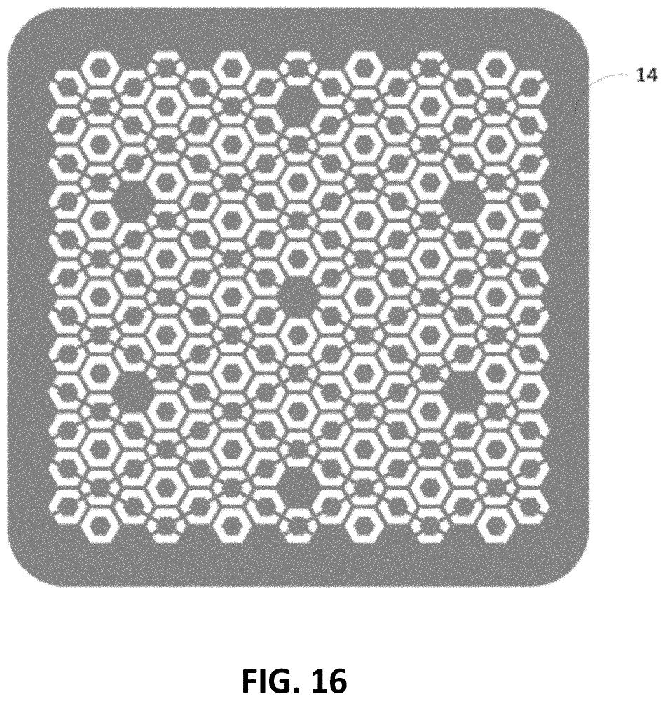

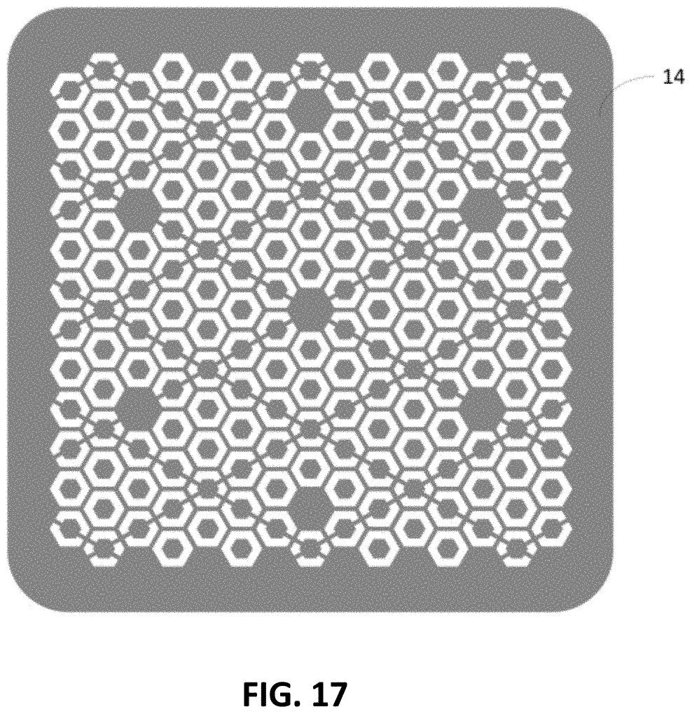

As shown in FIG. 15 for a fifth embodiment, a merged PiN Schottky (MPS) diode with a plasma spreading layer obtained by symmetric transformation. For instance, the plasma spreading layer shown in FIG. 15 is obtained by the symmetric transformation of the plasma spreading layer stricture shown in FIG. 6; and FIGS. 16 and 17 show different arrangements of the plasma spreading layer of the fifth embodiment on the MPS diode.

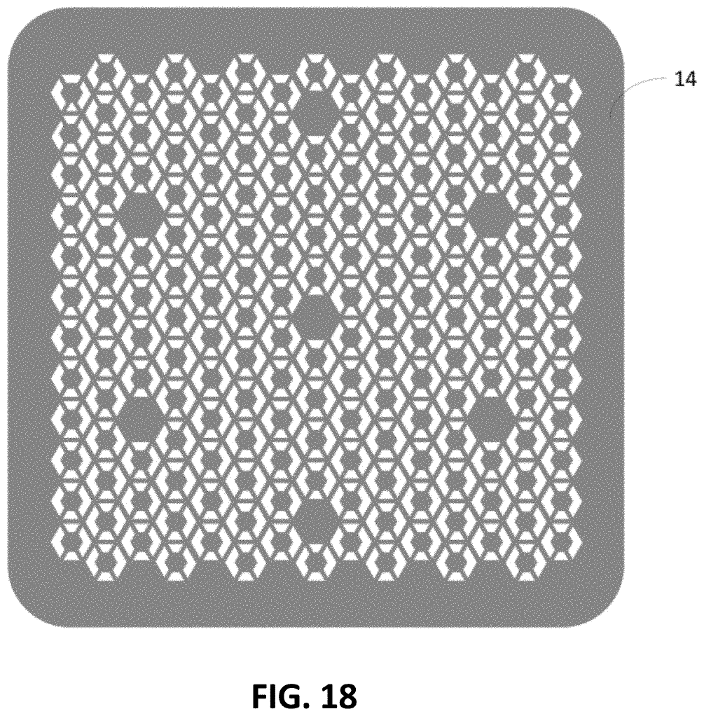

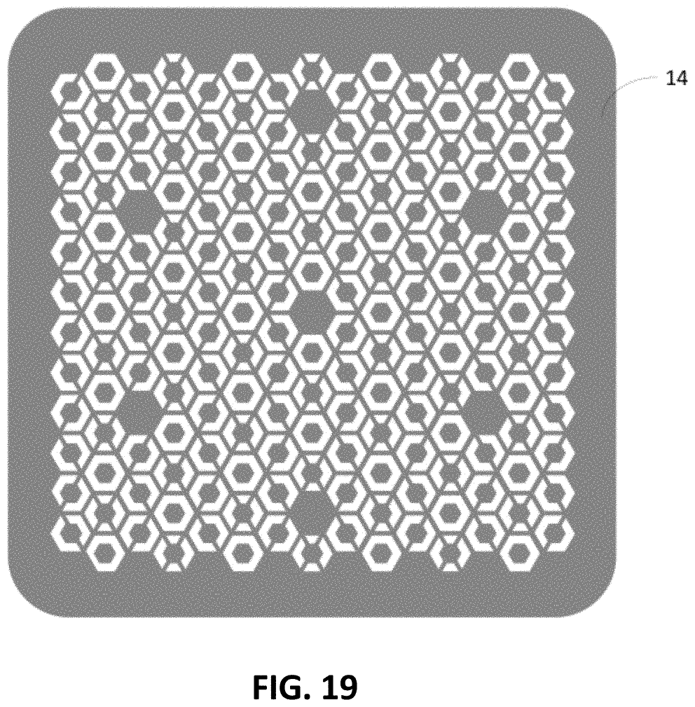

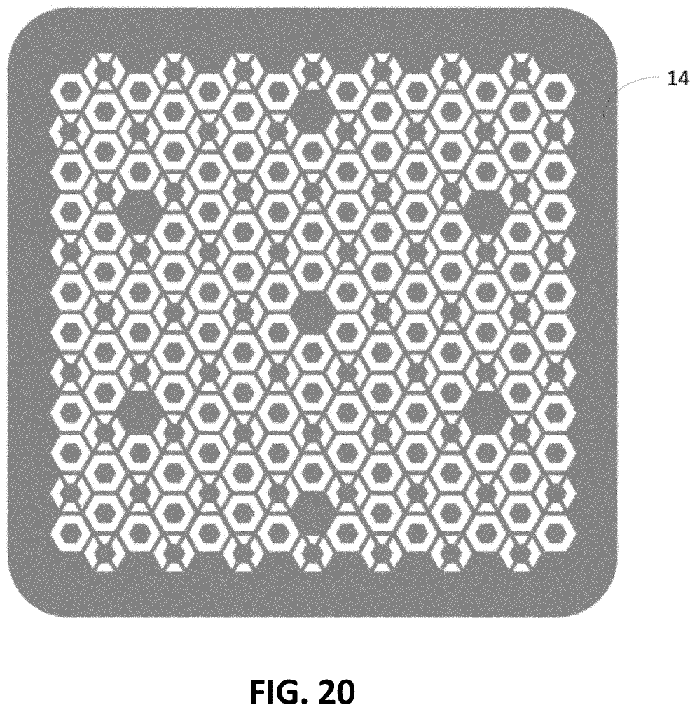

Similarly, a sixth embodiment of a layout design shown in FIG. 18 can be obtained after the symmetric transformation of the plasma spreading layer in FIG. 12; and FIGS. 19 and 20 show different arrangements of the plasma spreading layer of the sixth embodiment on the MPS diode.

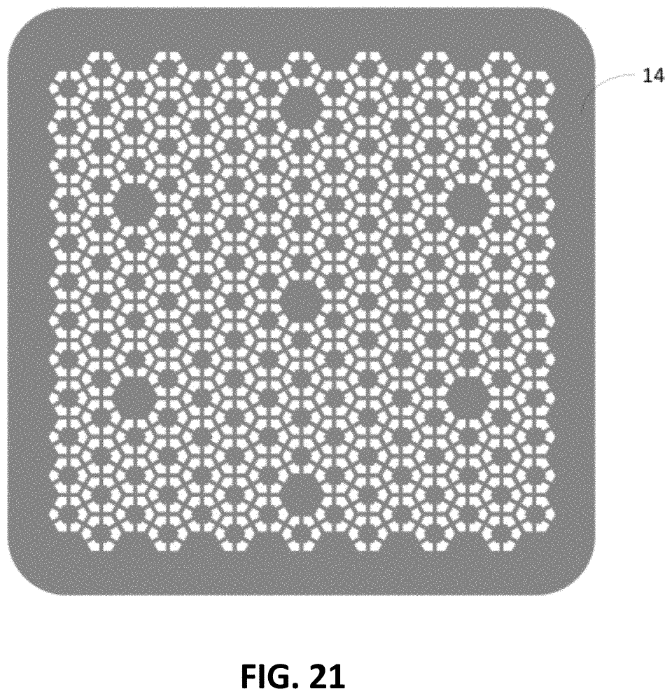

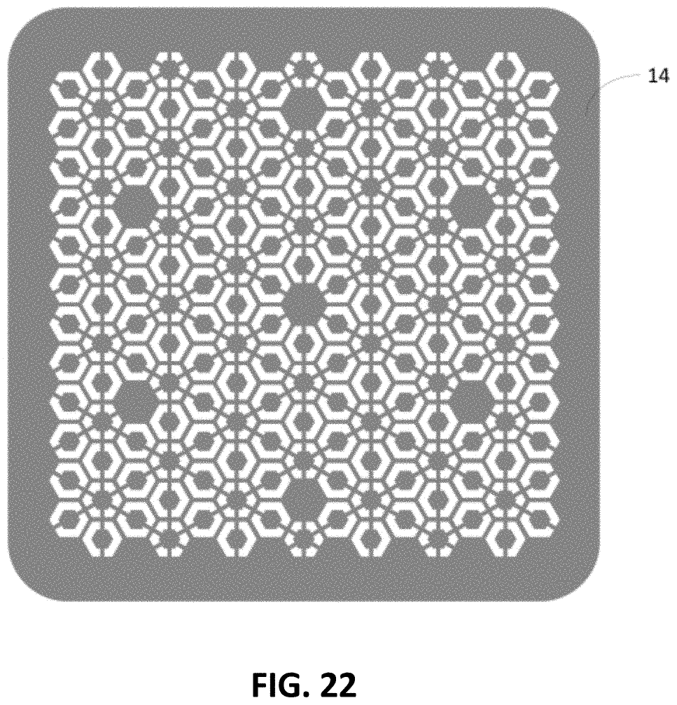

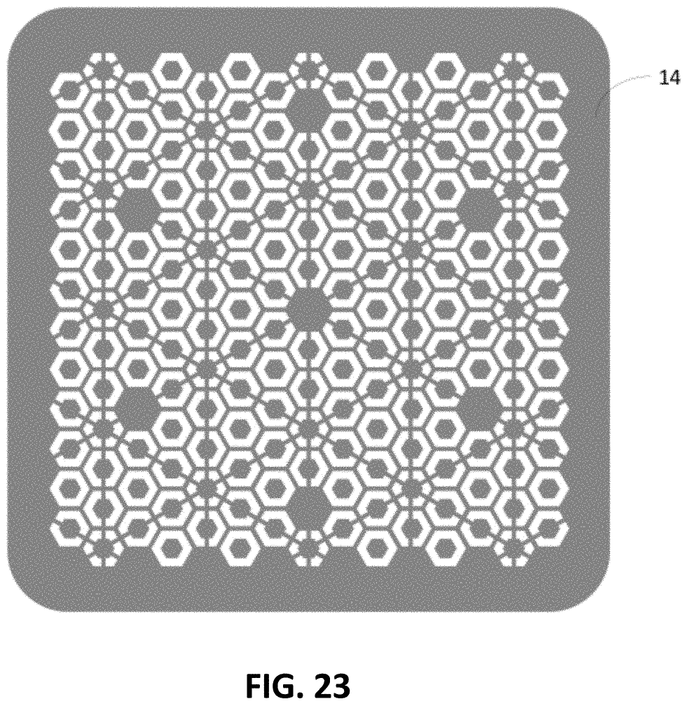

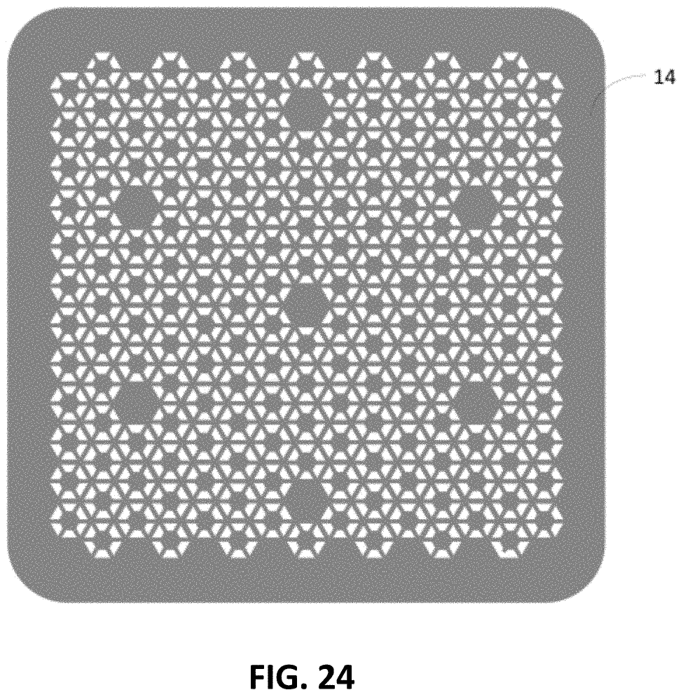

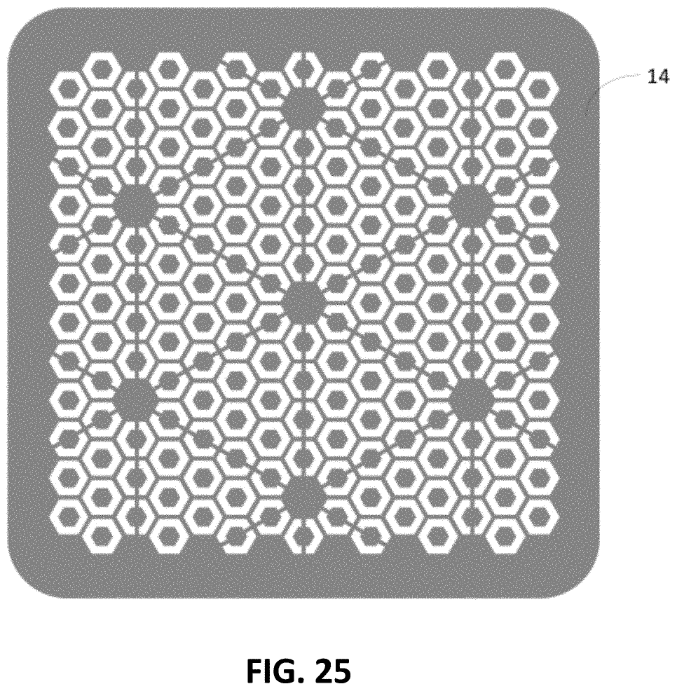

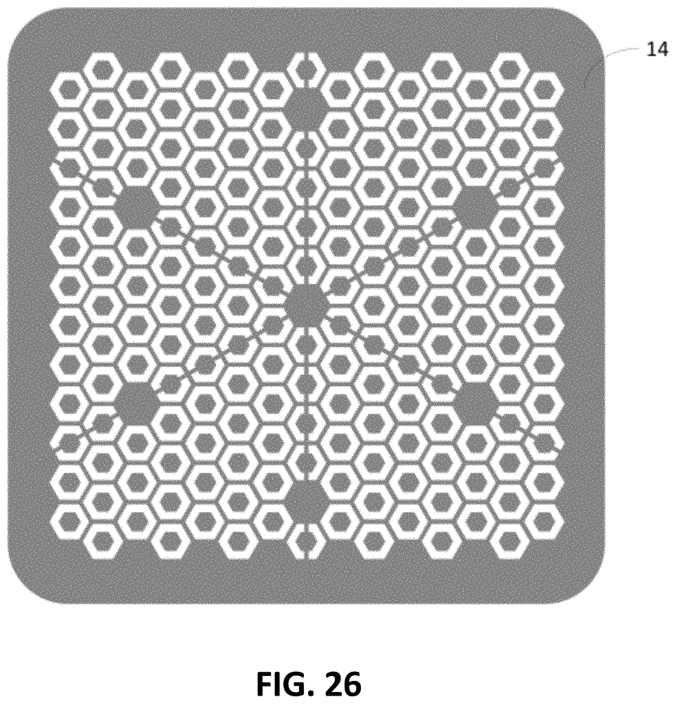

In addition to the symmetric transformation of rotated plasma spreading layer, based on the different design shown in FIG. 3 to FIG. 20, more layout designs with new cross-networking plasma spreading layer structure can be obtained through different combinations. Four instances are provided in FIGS. 21 to 26. It is important to note that the design of the plasma spreading layers in the present invention are also applicable to other hexagonal cells designs that may not be shown here. Moreover, the design of the plasma spreading layers in the present invention can also be applied to different geometric cells, such as circular cells, regular octagonal cells and other polygonal cells.

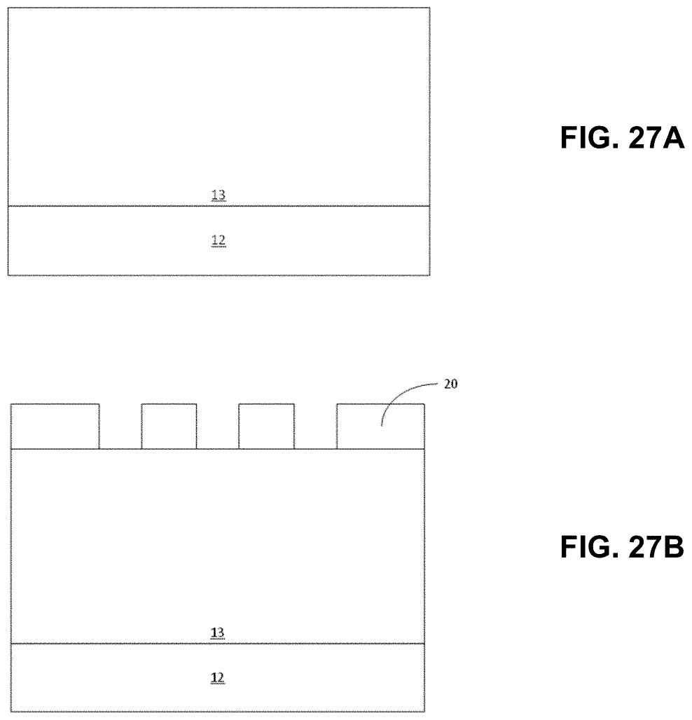

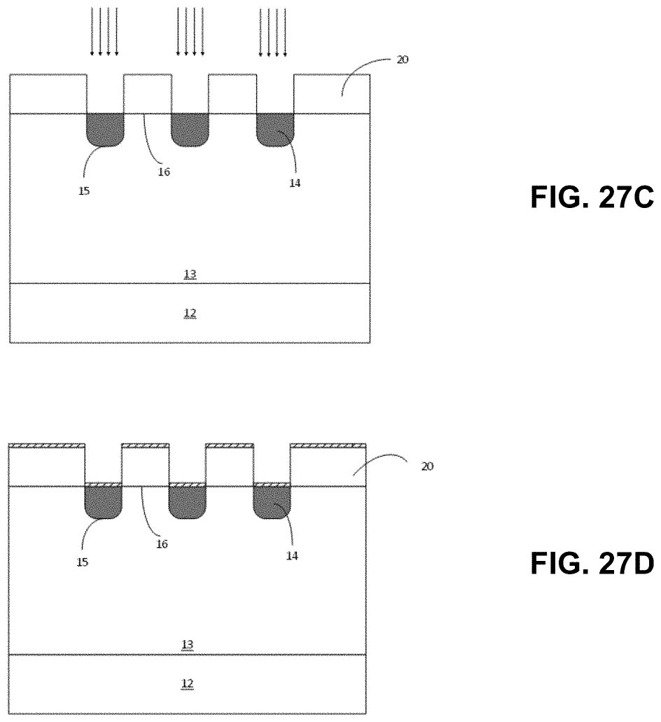

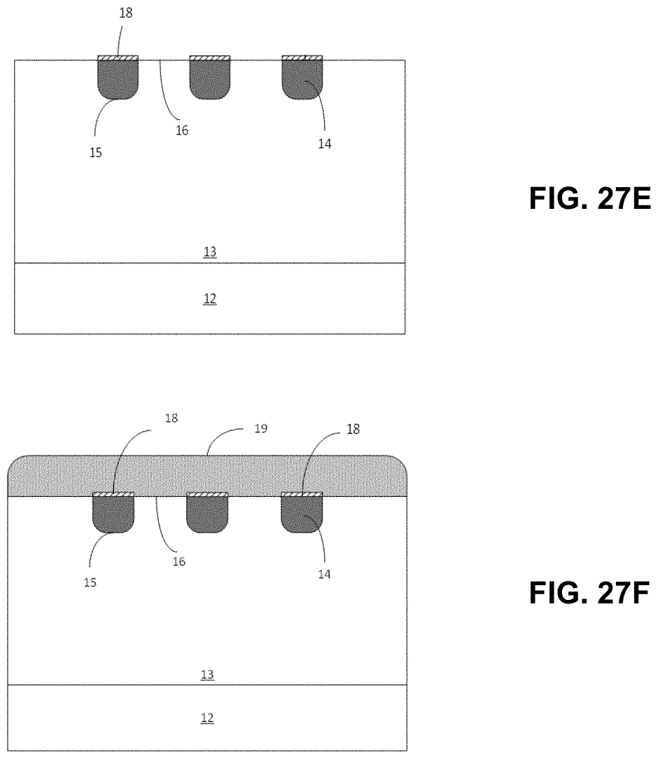

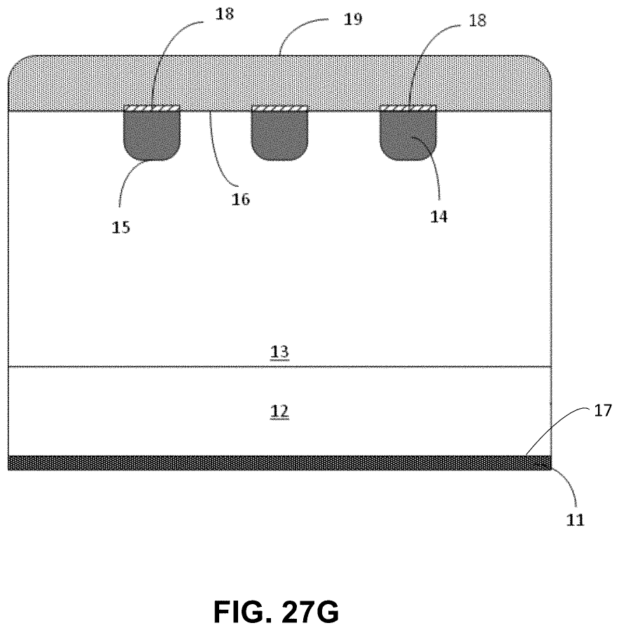

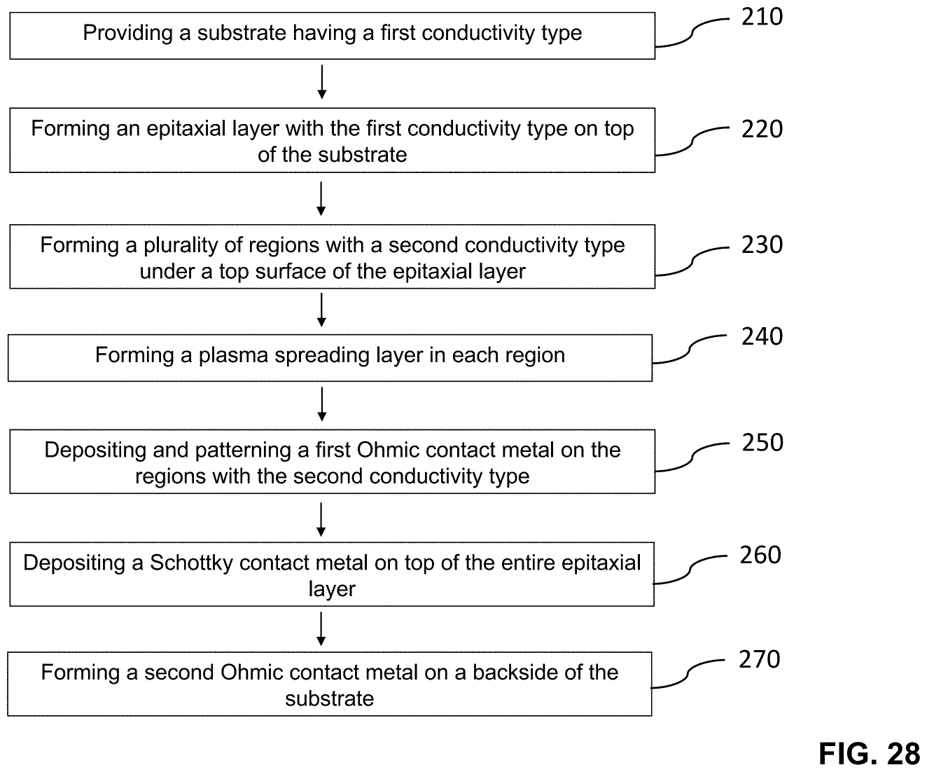

In another aspect, as shown in FIGS. 27A to 27G, and 28, a method for manufacturing a merged PiN Schottky (MPS) diode may include steps of providing a substrate having a first conductivity type 210; forming an epitaxial layer with the first conductivity type 220 on top of the substrate; forming a plurality of regions with a second conductivity type under a top surface of the epitaxial layer 230; forming a plasma spreading layer in each region 240; depositing and patterning an Ohmic contact metal on the regions with the second conductivity type 250; depositing a Schottky contact metal on top of the entire epitaxial layer 260; and forming an Ohmic contact metal on a backside of the substrate 270.

In one embodiment, the epitaxial layer is made of N-type silicon carbide. In another embodiment, the step of forming a plurality of regions with a second conductivity type under a top surface of the epitaxial layer 230 may include steps of depositing and patterning a mask layer 20 on the epitaxial layer 2301, implanting P-type dopant into the epitaxial layer 2302, and removing the mask layer 2303. It is noted that the dopant can be aluminum or boron.

In a further embodiment, the step of depositing and patterning an Ohmic contact metal on the regions 240 may include a step of annealing the Ohmic metal to enable the metal to be in direct contact with the epitaxial layer. In still a further embodiment, the step of depositing a Schottky contact metal on top of the entire epitaxial layer 250 may include a step of conducting a low temperature annealing of the Schottky contact metal.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A semiconductor device comprising:
a substrate having a first conductivity type;
an epitaxial layer having the first conductivity type deposited on one side of the substrate;
a plurality of regions having a second conductivity type formed under a top surface of the epitaxial layer;
a first Ohmic metal patterned and deposited on top of the regions with the second conductivity type;
a Schottky contact metal deposited on top of the entire epitaxial layer to form a Schottky junction; and
a second Ohmic metal deposited on a backside of the substrate,
wherein a plasma spreading layer is formed in each of the regions, and the plasma spreading layer is configured to diffuse plasma when a surge current occurs, so the surge current and heat generated inside the semiconductor device can be evenly and efficiently dispersed over the semiconductor device.

2. The semiconductor device of claim 1, wherein the first conductivity type is N-type and the second conductivity type is P-type; and each of the regions is a P+ region.

3. The semiconductor device of claim 1, wherein the semiconductor device is a merged PiN Schottky (MPS) diode.

4. The semiconductor device of claim 2, wherein a PN junction formed between each of the P+ regions and N-type drift regions is turned on when the surge current occurs, and plasmas are generated under the PN junction.

5. The semiconductor device of claim 2, wherein each P+ region has a plurality of hexagonal cells with one or more P+ rings and a plasma spreading layer that has a plurality of P+ type diagonal lines passing through the hexagonal cells and P+ rings.

6. The semiconductor device of claim 2, wherein the plasma spreading layer can be formed in other shapes.

7. The semiconductor device of claim 4, wherein each P+ region has a plurality of hexagonal cells with one or more P+ rings and a plasma spreading layer that has a plurality of P+ type diagonal lines passing through the hexagonal cells and P+ rings.

8. The semiconductor device of claim 4, wherein the plasma spreading layer can be formed in other shapes.

9. A method for manufacturing a merged PiN Schottky (MPS) diode comprising steps of:
providing a substrate having a first conductivity type;
forming an epitaxial layer with the first conductivity type on top of the substrate;
forming a plurality of regions with a second conductivity type under a top surface of the epitaxial layer;
forming a plasma spreading layer in each region;
depositing and patterning a first Ohmic contact metal on the regions with the second conductivity type;
depositing a Schottky contact metal on top of the entire epitaxial layer; and
forming a second Ohmic contact metal on a backside of the substrate,
wherein the plasma spreading layer is configured to diffuse plasma when a surge current occurs, so the surge current and heat generated inside the semiconductor device can be evenly and efficiently dispersed over the MPS diode.

10. The method for manufacturing a merged PiN Schottky (MPS) diode of claim 9, wherein the first conductivity type is N-type and the second conductivity type is P-type; and each of the regions is a P+ region.

11. The method for manufacturing a merged PiN Schottky (MPS) diode of claim 10, wherein a PN junction formed between each of the P+ regions and N− type drift regions is turned on when the surge current occurs, and plasmas are generated under the PN junction.

12. The method for manufacturing a merged PiN Schottky (MPS) diode of claim 10, wherein each P+ region has a plurality of hexagonal cells with one or more P+ rings, and a plasma spreading layer that has a plurality of P+ type diagonal lines passing through the hexagonal cells and P+ rings.

13. The method for manufacturing a merged PiN Schottky (MPS) diode of claim 9, wherein the plasma spreading layer can be formed in other shapes.

14. The method for manufacturing a merged PiN Schottky (MPS) diode of claim 11, wherein each P+ region has a plurality of hexagonal cells with one or more P+ rings, and a plasma spreading layer that has a plurality of P+ type diagonal lines passing through the hexagonal cells and P+ rings.

15. The method for manufacturing a merged PiN Schottky (MPS) diode of claim 10, wherein the plasma spreading layer can be formed in other shapes.
